(19) United States
(12) Patent Application Publication
(10) Pub. No.: US 2008/0217672 A1
(43) Pub. Date: Sep. 11, 2008

(54) INTEGRATED CIRCUIT HAVING A MEMORY

(75) Inventors: Martin Popp, Dresden (DE); Ulrike Gruening-von Schwerin, Muenchen (DE); Till Schloesser, Dresden (DE); Peter Lahnor, Dresden (DE); Rolf Weis, Dresden (DE); Odo Wunnicke, Dresden (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 11/684,033

(22) Filed: Mar. 9, 2007

(51) Int. Cl. H01G 4/40; H01L 21/62; H01L 27/01

(52) U.S. Cl. 257/305; 257/534; 361/328; 438/386; 257/E27.092; 257/E21.014; 257/E21.02

(57) ABSTRACT

An integrated circuit having a memory arrangement including capacitor elements and further capacitor elements is disclosed. One embodiment provides a substrate layer with contact pads and further contact pads; the capacitor elements being disposed in a first level on the substrate layer and connected with the contact pads; the further capacitor elements being disposed in a second level above the first level; contact elements being disposed between the capacitor elements and connected with the further contact pads; the further capacitor elements being disposed above the contact elements and being connected with the contact elements.

### BACKGROUND

The present invention refers to an arrangement of capacitor elements, to memories with memory cells and to a method of fabricating an arrangement with capacitor elements.

Conventional memories include memory cells that are arranged on a support layer, wherein the memory cells are constructed as capacitor elements. The capacitor element may include a bottom plate covered by a dielectric layer. The dielectric layer is covered with a top plate. The capacitor may have the structure of a cylinder capacitor, of a cup cylinder or of a block capacitor. The need for higher integration of memory cells results in capacitor elements covering a smaller area of the support layer. As a result, the capacitor elements are formed by structures that extend from the support layer in a vertical direction up to a height that can be attained by fabricating the capacitor elements. The horizontal area of the substrate is limited and therefore, the capacitor elements are fabricated with a high aspect ratio. Furthermore, dielectric material is used having a high-k coefficient in order to provide a large amount of electrical charge which can be stored in a small capacitor element.

For these and other reasons, there is a need for the present invention.

### SUMMARY

One embodiment provides an integrated circuit having a memory with memory cells with capacitor elements and with memory cells with further capacitor elements with a substrate layer with contact pads and further contact pads. The capacitor elements being disposed in a first level on the substrate layer and connected with the contact pads. The further capacitor elements being disposed in a second level above the first level. The contact elements being disposed between the capacitor elements and connected with the further contact pads. The further capacitor elements being disposed above the contact elements and being connected with the contact elements. A method of making an integrated circuit is also disclosed.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 illustrates a schematic drawing of a first process.

FIG. 2 illustrates a schematic drawing of a second process.

FIG. 3 illustrates a schematic drawing of a third process.

FIG. 4 illustrates a schematic drawing of a fourth process.

FIG. 5 illustrates a schematic drawing of a fifth process.

FIG. 6 illustrates a schematic drawing of a sixth process.

FIG. 7 illustrates a schematic drawing of a seventh process.

FIG. 8 illustrates a schematic drawing of an eighth process.

FIG. 9 illustrates a top view onto a structure of the eighth process.

FIG. 10 illustrates a schematic drawing of the structure after etching a recess.

FIG. 11 illustrates a top view onto the structure of FIG. 10.

FIG. 12 illustrates a schematic drawing after a metal-fillprocess.

FIG. 13 illustrates a top view onto the structure of FIG. 12.

FIG. 14 illustrates a schematic drawing after a deposition of a dielectric liner.

FIG. 15 illustrates a schematic sectional view of a structure with a first level of capacitor elements covered by a second level.

FIG. 16 illustrates the structure of FIG. 15 after the deposition of a bottom electrode layer.

FIG. 17 illustrates a capacitor element of a second level arranged on a first level of capacitor elements.

FIG. 18 illustrates a further process with openings in a part of the capacitor elements of the first level.

FIG. 19 illustrates a structure with a first level of capacitor elements and a second level of further capacitor elements.

FIG. 20 illustrates a top view on the arrangement of the capacitor elements of the first level and the further capacitor elements of the second level of FIG. 19.

FIG. 21 illustrates a top view on a further arrangement of capacitor elements in a first level and further capacitor elements in a second level.

FIG. 22 illustrates a top view on a third arrangement of capacitor elements in a first level and further capacitor elements of a second level.

FIG. 23 illustrates a top view onto an arrangement of block capacitor elements with cross-sectional lines A-A and B-B.

FIG. 24 illustrates a sectional view of the block capacitor elements in the sectional line A-A of FIG. 23.

FIG. 25 illustrates a sectional view along the sectional line B-B line of FIG. 23.

FIG. 26 illustrates the block capacitors with a dielectric liner.

FIG. 27 illustrates the block capacitors with a dielectric liner in the sectional line B-B.

FIG. 28 illustrates the capacitors after removing a part of the dielectric liner.

FIG. 29 illustrates the structure of FIG. 28 in the sectional line B-B after removing a part of the dielectric liner.

FIG. 30 illustrates the capacitors after filling conductive material into the recess between the two capacitors.

FIG. 31 illustrates a sectional view in the sectional line B-B after the conductive-fill.

FIG. 32 illustrates a sectional view of a capacitor arrangement with block capacitors in a first and in a second level.

FIG. 33 illustrates a first embodiment with a third layer.

FIG. 34 illustrates a further embodiment with a third layer.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

The present invention generally relates to an arrangement of capacitor elements. Furthermore the invention relates to integrated circuit, and to a memory circuit with an arrangement of capacitor elements. The invention also relates to programmable structures suitable for various integrated circuit applications, for example, in memory devices.

Embodiment of the present invention may be described in terms of various functional components. It should be appreciated that such functional components may be realized by any number of hardware or structural components configured to perform the specified functions. For example, the present invention may employ various integrated components comprised of various electrically devices, such as resistors, transistors, capacitors, diodes and such components, the behaviour of which may be suitably configured for various intended purposes. In addition, the present invention may be practised in any integrated circuit application where an effective reversible polarity is desired. Such general applications may be appreciated by those skilled in the art in light of the present disclosure are not described in detail. Further, it should be noted that various components may be suitably coupled or connected to other components within exemplary circuits, and that such connections and couplings can be realized by direct connection between components and by connections through other components and devices located in between.

One embodiment provides an integrated circuit having a memory with memory cells with capacitor elements and with memory cells with further capacitor elements with a substrate layer with contact pads and further contact pads. The capacitor elements being disposed in a first level on the substrate layer and connected with the contact pads. The further capacitor elements being disposed in a second level above the first level. The contact elements being disposed between the capacitor elements and connected with the further contact pads. The further capacitor elements being disposed above the contact elements and being connected with the contact elements.

Another embodiment provides a method of fabricating an arrangement with capacitor elements including: providing a substrate layer with first and second contact pads; depositing a first layer with capacitor elements with at least a first electrode; depositing the first electrodes at least partially on the first contact pads; depositing contact elements on the second contact pads; depositing a second layer with further capacitor elements on the first layer; the further capacitor elements being fabricated with first electrodes that are at least partially deposited on the contact elements. The method may be used for fabricating a memory circuit.

Another embodiment provides an arrangement with capacitor elements and further capacitor elements, with a substrate layer with contact pads and further contact pads. The capacitor elements are disposed in a first level on the substrate layer and connected with the contact pads. The further capacitor elements are disposed in a second level above the first level. The contact elements are disposed between the capacitor elements and connected with the further contact pads. The further capacitor elements are disposed above the contact elements and connected with the contact elements.

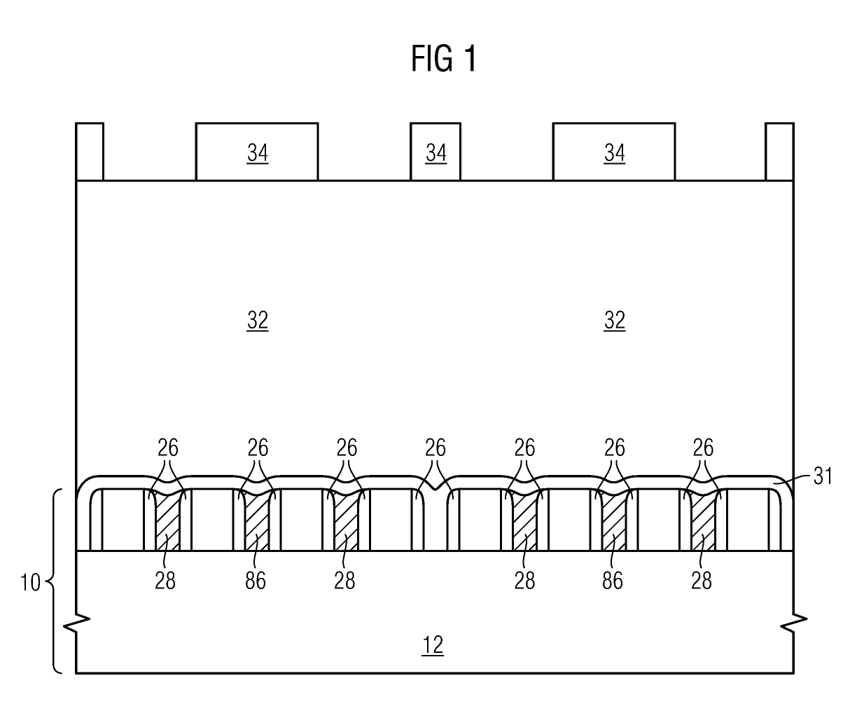

FIGS. 1 to 7 illustrate a method for forming an arrangement having a plurality of cylindrical capacitors, e.g., from metal. FIG. 1 illustrates a layer 10 having a plurality of contact pads 28 and second contact pads 86 in an upper region of the layer 10. Insulating spacers 26 may be formed for insulating the contact pads 28 and/or the second contact pads 86. The spacers may be made of silicon nitride. The contact pads 28 and the second contact pads 86 may be formed by polysilicon or metal. An etch stop layer 31 is formed on the first and second contact pads 28, 86 and on the spacers, then a thick layer of deposited oxide 32, e.g., made of boron phosphor silicate glass (BPSG), is formed to provide a base dielectric layer for the capacitor features that will be formed later. A patterned photoresist layer 34 defines the location of the cylinder capacitors to be formed. The FIG. 1 structure may include one or more bit lines under the BPSG layer or various other structural elements or differences which, for simplicity of explanation, have not been illustrated. The layer 10 may be arranged on a wafer 12 for example a semiconductor wafer, i.e. a silicon wafer.

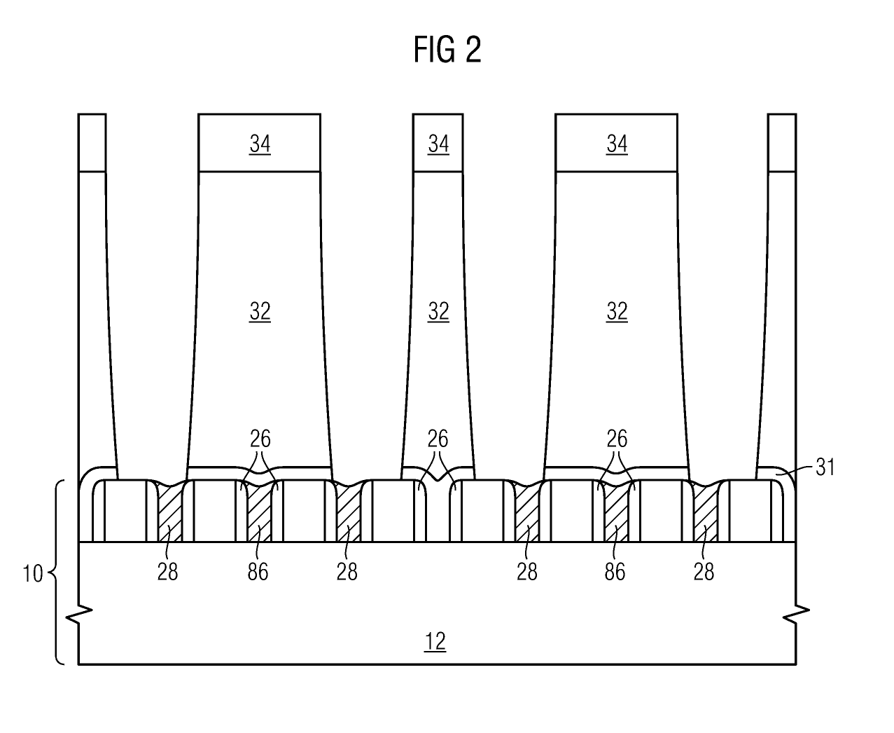

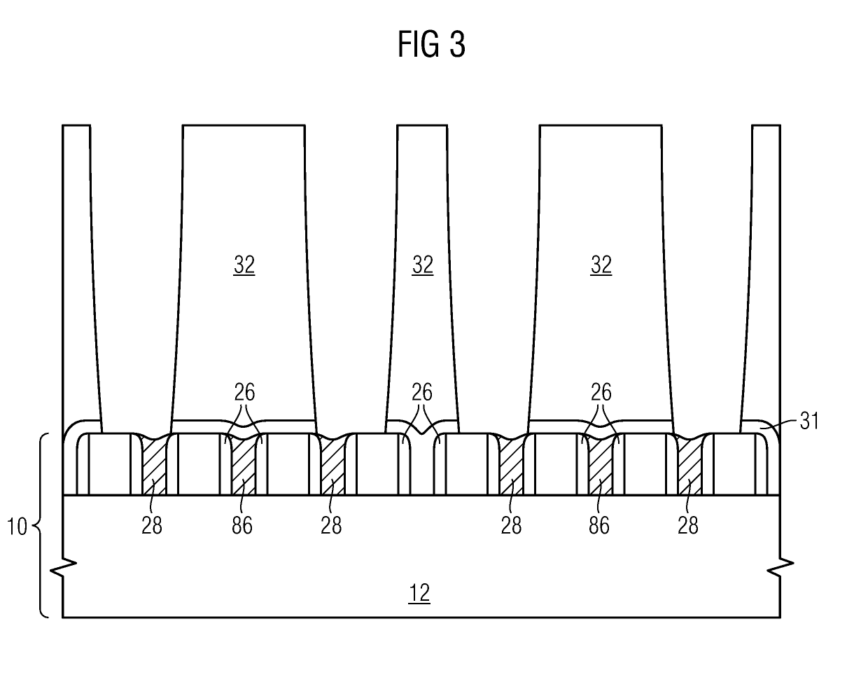

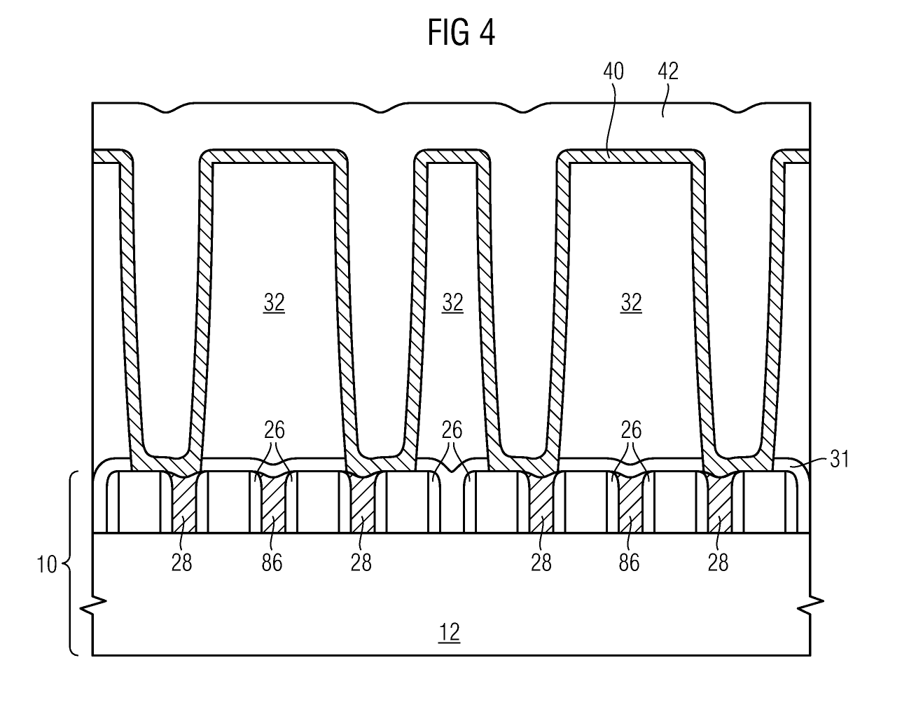

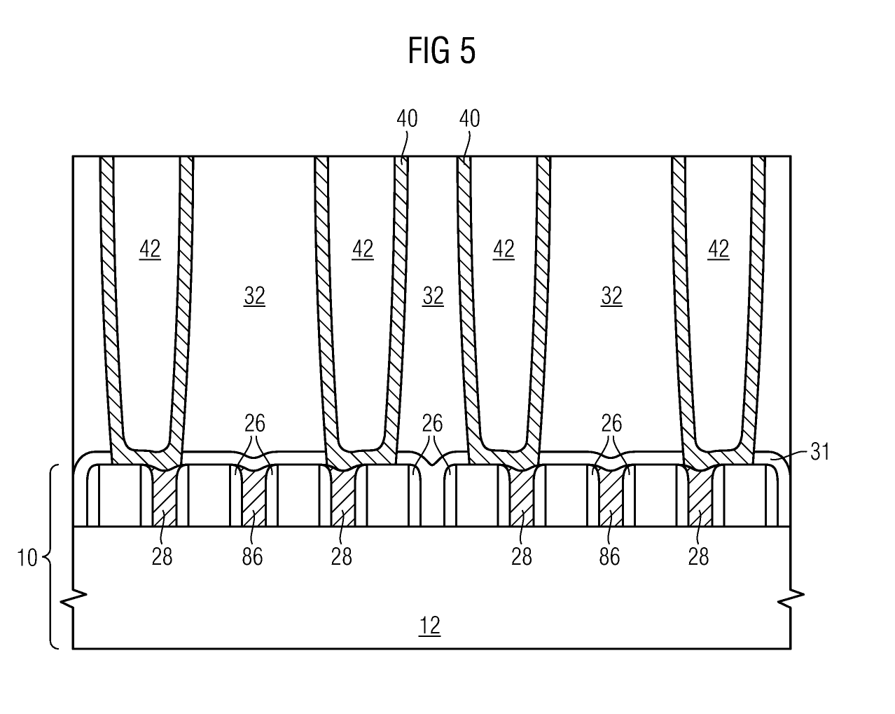

The FIG. 1 structure is subjected to an anisotropic etch which removes the exposed portions of the oxide layer 32 to expose the etch stop layer 31 and form a patterned oxide layer 32 which provides a base dielectric having recesses for the capacitors. The exposed portion of the etch stop is then removed. Subsequent to the etching of the etch stop 31, the contact pads 28 and the further contact pads 86 are exposed to result in a structure as illustrated in FIG. 2. The remaining photoresist layer 34 is stripped and any polymer (not illustrated) that forms during the etch is removed according to means known in the art to provide a structure as illustrated in FIG. 3. As illustrated in FIG. 4, a conductive layer 40 such as metal or polysilicon or another conductive material is formed conformal with the deposited oxide layer 32, and will provide a capacitor bottom electrode for the completed capacitor. A thick filler material 42, such as photoresist, is formed to fill the cylinders provided by the conductive layer 40. The FIG. 4 structure is then subjected to a planarizing process such as a chemical planarization, a mechanical planarization, or a chemical-mechanical planarization step. From the photoresist 42 this process removes the conductive layer 40 and usually a portion of the oxide layer 32 to result in a structure as illustrated in FIG. 5.

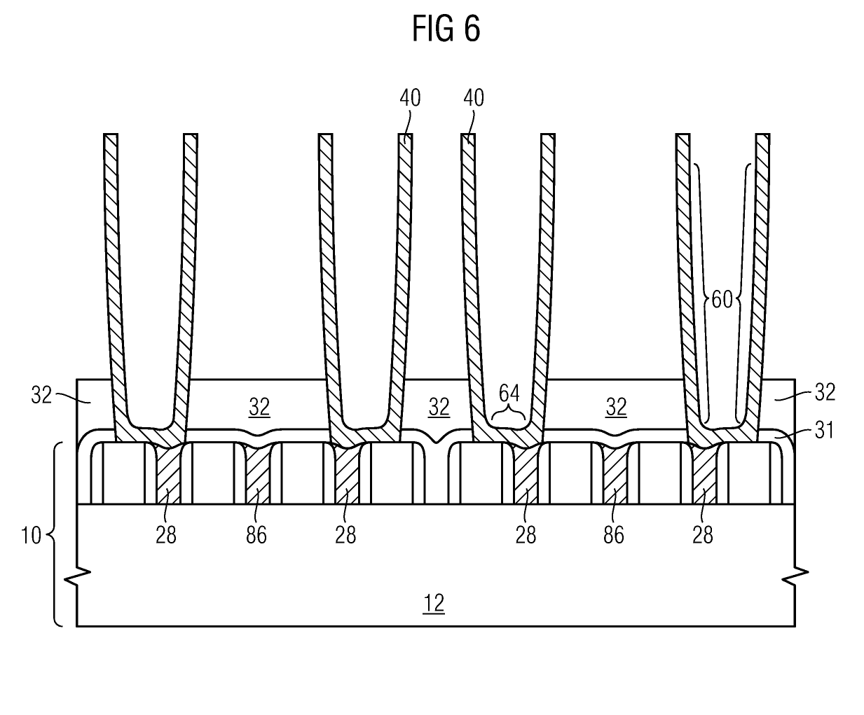

Next, the oxide layer 32 is partially etched with an etch selective to the conductive layer 40 to result in a structure as illustrated in FIG. 6. The conductive layer 40 constitutes a bottom plate basically including the structure of a cup. Sidewall of the cup is vertically oriented and a bottom of the cup is horizontally oriented and electrically coupled to the contact pads 28.

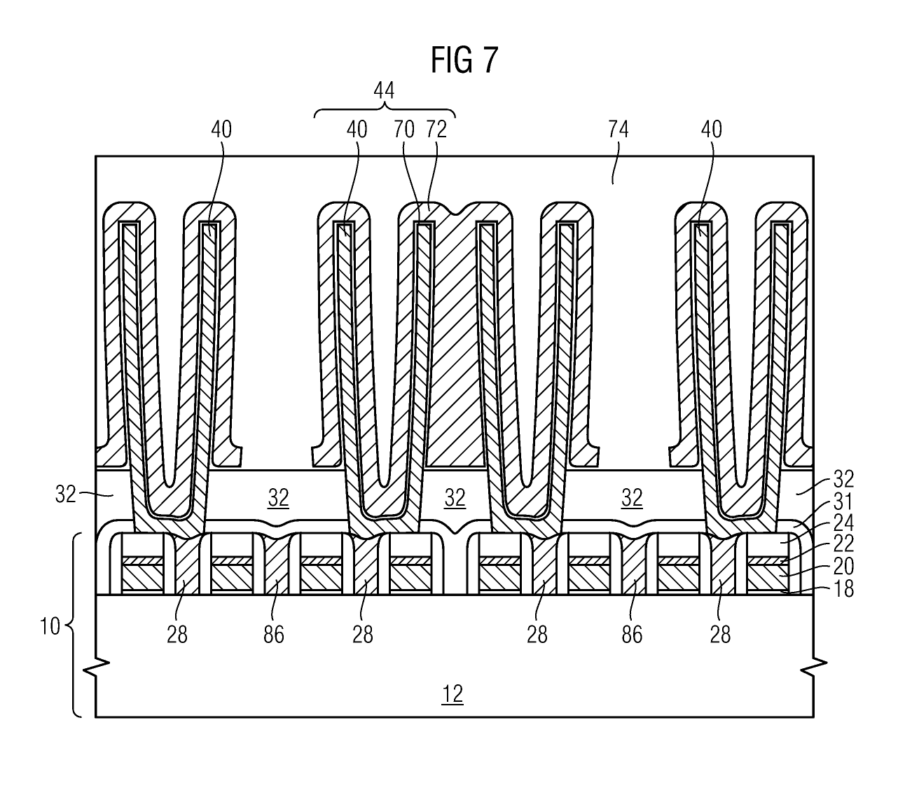

Next, a dielectric layer 70, e.g., a layer of high quality nitride, and an electrically conductive layer as a top electrode 72 are formed at an inner side and an outer side of the sidewall of the cylinder shape of the bottom plate 40, as illustrated in FIG. 7. The dielectric layer may also be made of a high k-coefficient material. The second electrode 72 does not cover the whole surface of the oxide 32. The structure is filled up with a dielectric material 74 made of electrically insulating material. The dielectric material may be for example be made of silicon oxide. Depending on the embodiment also other dielectric material may be used. This forms a double-sided cylinder capacitor as both the capacitor dielectric layer 70 and the capacitor top layer 72 follow the contours of the majority of both the inside face and the outside face of each bottom plate 40.

Depending on the embodiment, use may also be made of a cylinder capacitor with a one-sided shape, meaning that the dielectric layer 70 and the top plate 72 are only disposed on an inner face or on an outer face of the bottom plate 40. The first electrode 40, the dielectric layer 70 and the second electrode 72 constitute a cylinder capacitor 44. The dielectric layer 70 may include HfOx, HfSiOx, HfAlOx, ZrOx, ZrSiOx, ZrAlOx, ZrAOx, whereby A as an element of the rare earth groups.

The first and/or the second electrode 40, 72 may include at least partially metallic material for example TiN, TaN, Ru, Ir or C.

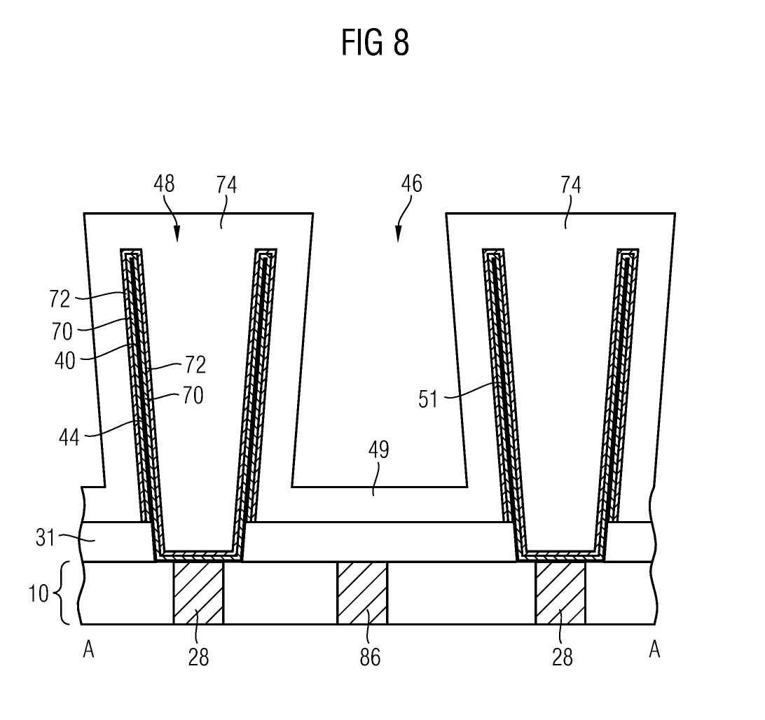

FIG. 8 illustrates the structure of FIG. 7 wherein only an upper section is illustrated and some detailed information is not explicitly illustrated. Furthermore, the oxide layer 32 is completely removed. The dielectric material 74 is removed in a recess area 46 between two adjacent cylinder capacitors above second contact pads 86. The cylinder capacitor is illustrated as a simple U-shaped structure for the cylinder capacitor 44. The cylinder capacitor 44 includes the first electrode 40, the dielectric layer 70 and the second electrode 72. The first electrode 40 is covered on two sides by the dielectric layer 70. The dielectric layer 70 is covered by a second electrode 72 on the two sides. The whole structure is embedded in the dielectric material 74. An inner region 48 of the cylinder capacitor 44 is also filled with the dielectric material 74. Depending on the embodiment, the dielectric material 74 may be deposited as it is illustrated in FIG. 8 or as illustrated in FIG. 7 covering the whole structure, wherein in contact areas 46 between two cylinder capacitors 44, 50 the dielectric material 74 is partly removed leaving a remaining layer 49. The contact area 46 is arranged above a second contact pad 86 which is arranged between two contact pads 28 of cylinder capacitors of the first level and which is not connected to a first electrode 40 of a cylinder capacitor 44, 51. The first electrodes 40 of the illustrated cylinder capacitors 44, 51 are connected to a respective contact pad 28.

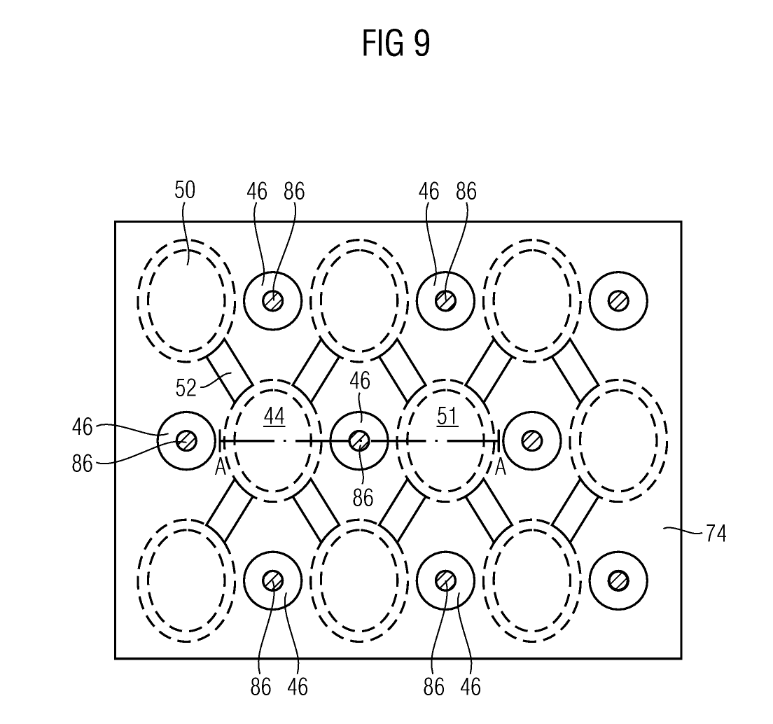

FIG. 9 illustrates a schematic view on several cylinder capacitors 44, 50, 51. In a first direction, i.e. the direction with the shortest distance to another cylinder capacitor 44, the dielectric material 74 is filled up to a height that is above the structure of the cylinder capacitor 44, 51. This means that each cylinder capacitor 44, 51 is connected by four spacer bridges 52 with four cylinder capacitor structures. Furthermore, each cylinder capacitor 44 is surrounded by four contact areas 46 at which a small remaining layer 49 of dielectric material 74 is disposed on the etch stop layer 31 above a second contact pad 86.

The cylinder capacitors 44, 50, 51 are illustrated as oval faces with a ring of a white dashed line. In the illustrated embodiment, a cylinder capacitor 44 is connected by a spacer bridge 52 to a second cylinder capacitor 50. The spacer bridge 52 defines a small connection stripe at the height of an upper face of the dielectric material 74. Furthermore, between the cylinder capacitor 44 and a third cylinder capacitor 51 the contact area with a remaining layer 49 is disposed. FIG. 8 illustrates the cylinder capacitor 44 and the third cylinder capacitors 51 in a sectional view along the section line A-A of FIG. 9.

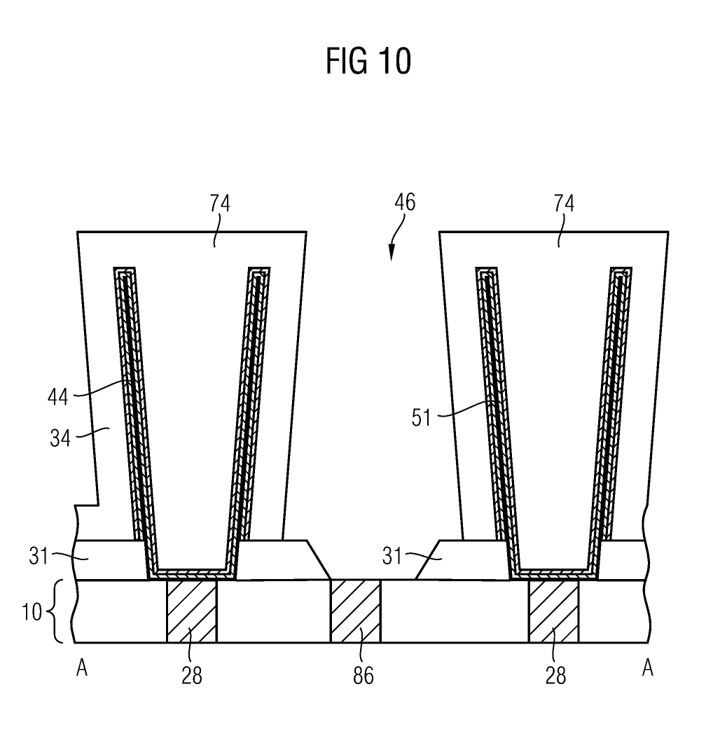

In one embodiment, the remaining layer 49 is removed by an etching process in the contact area 46 above the second contact pad 86. Furthermore, the etch stop layer 31 which is for example made of silicon nitride is removed, thereby opening an upper face of the second contact pad 86. This process is illustrated in FIG. 10.

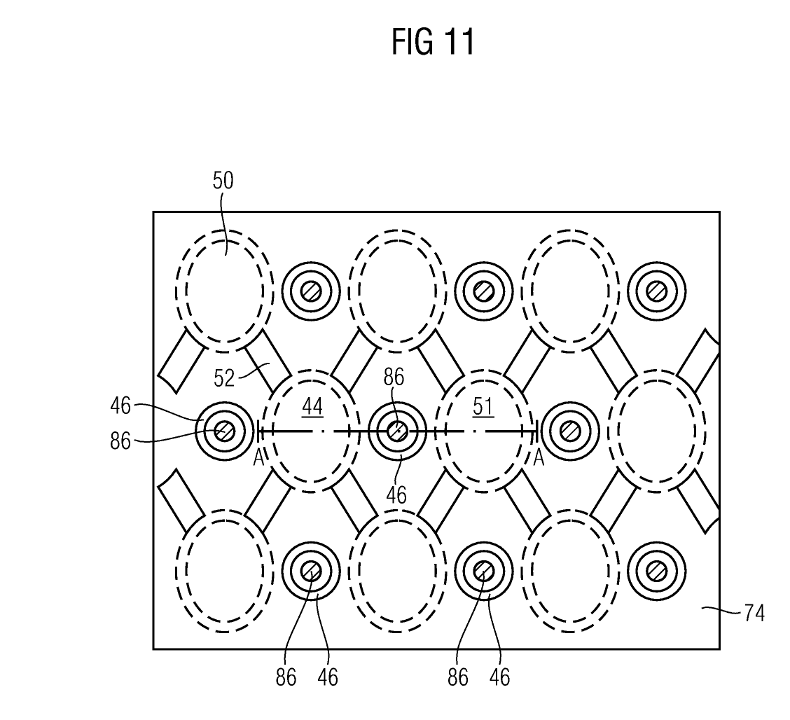

FIG. 11 illustrates a top view on the arrangement of cylinder capacitors 44, 50, 51 with free accessible second contact pads 86 in contact areas 46.

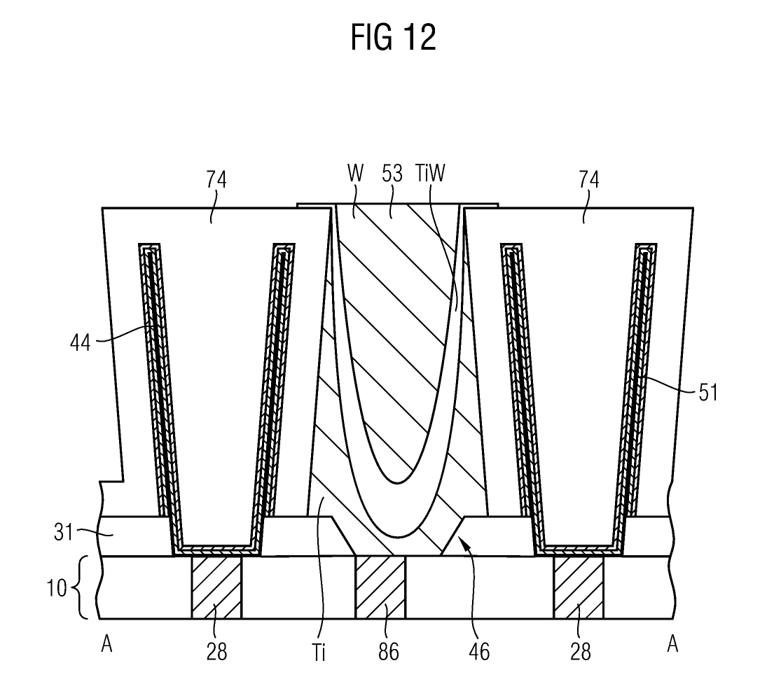

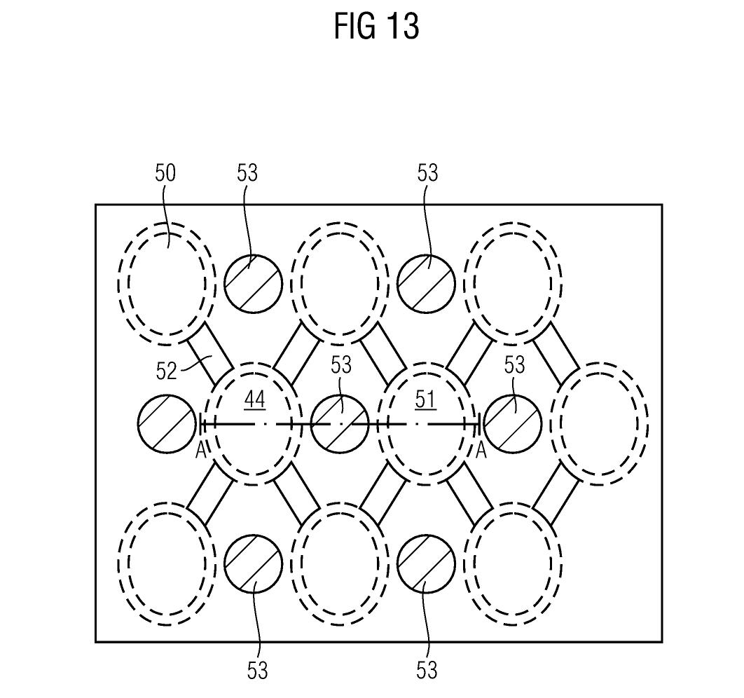

The contact areas 46 are filled with electrical conductive material 53 disposing contact elements. As material e.g., metal may be used. As a metal, use could e.g., be made of tungsten or a stacked layer including a first layer made of Ti, a second layer made of TiW and a third layer, made of W, whereby the second layer is arranged between the first and the third layer. After filling the contact area 46, a polishing process may be employed in order to planarize the conductive material 53 on the face of the dielectric material 74. This process is illustrated in FIG. 12. FIG. 13 illustrates a top view on the arrangement of FIG. 12.

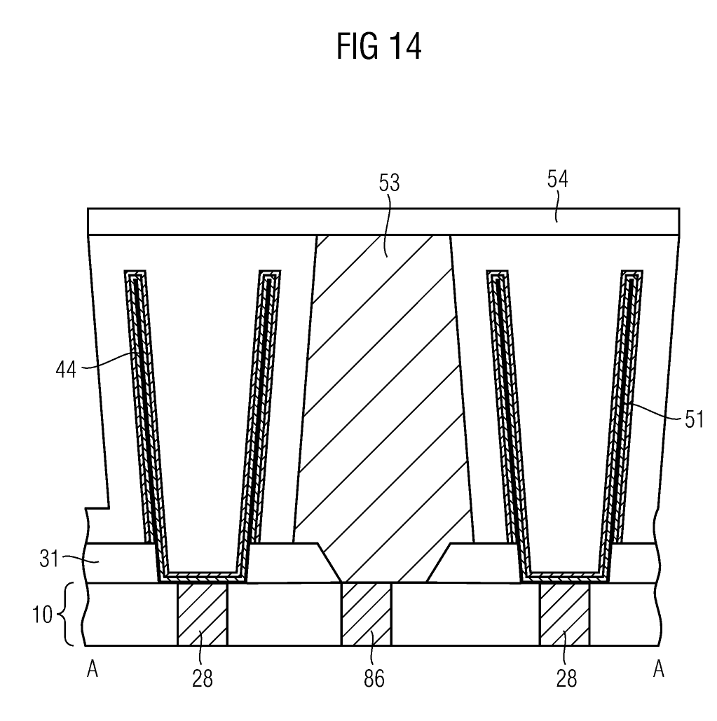

In another process, a dielectric liner 54 is deposited on the surface of the arrangement covering the dielectric material 74 and the conductive material 53. As material for the dielectric liner, e.g., silicon nitride may be used. This process is illustrated in FIG. 14.

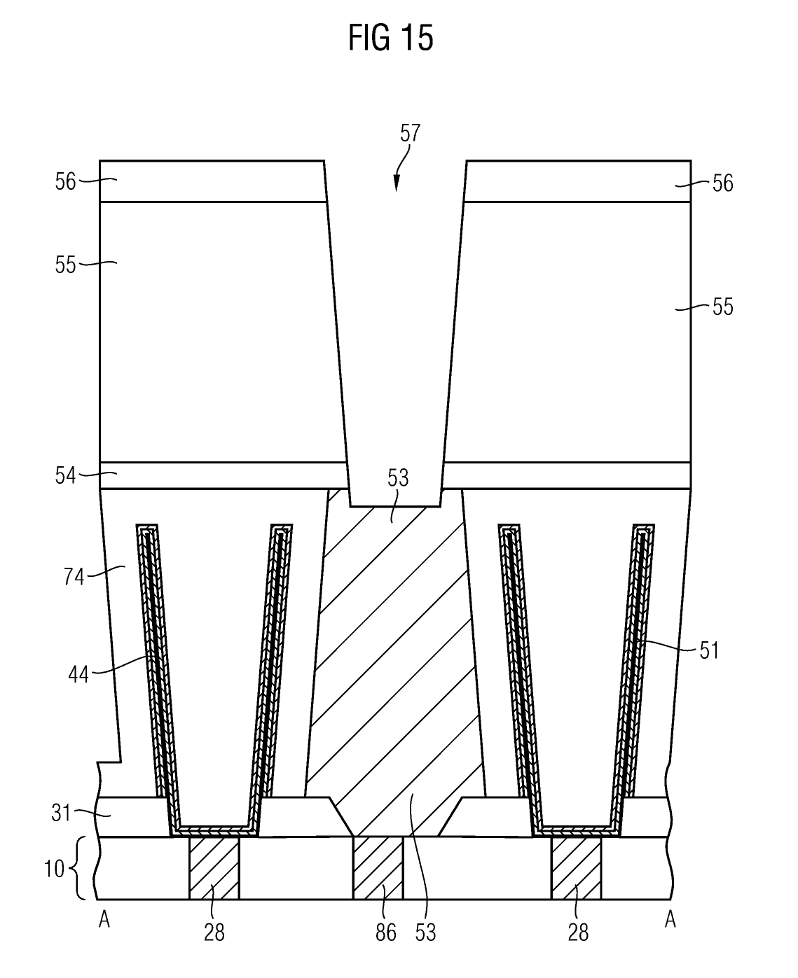

Next, a second oxide layer 55 is deposited on the dielectric liner 54. Then a second photoresist layer 56 is deposited on the second oxide layer wherein the second photoresist layer 56 is structured to provide a free face of the second oxide layer 55 at which a further cylinder capacitor may be fabricated. Then the second oxide layer 55 is removed by providing a cylinder opening 57 in the second oxide layer 55. Furthermore, the dielectric liner 54 and may be a part of the conductive material 53 is removed as a part of the cylinder opening 57. The cylinder opening 57 is arranged above, the conductive material 53 and directly adjacent to the conductive material 53 as illustrated in FIG. 15.

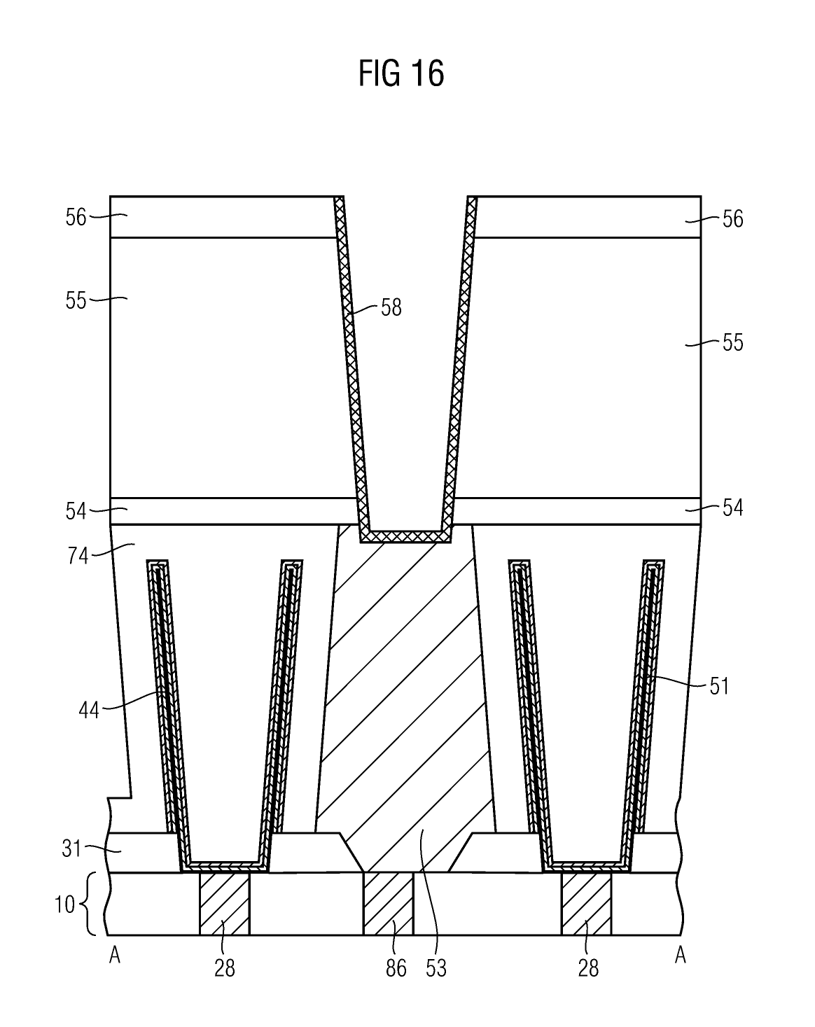

In another process, a first electrode 58 is deposited on the inner face of the cylinder opening 57 as illustrated in FIG. 16. The further first electrode 58 is deposited as an electrical conductive layer, e.g., made of polysilicon or metal. The further first electrode 58 may have the same shape as the first electrode 40 of the first or second cylinder capacitor 44, 51 of the first level. This process is illustrated in FIG. 16.

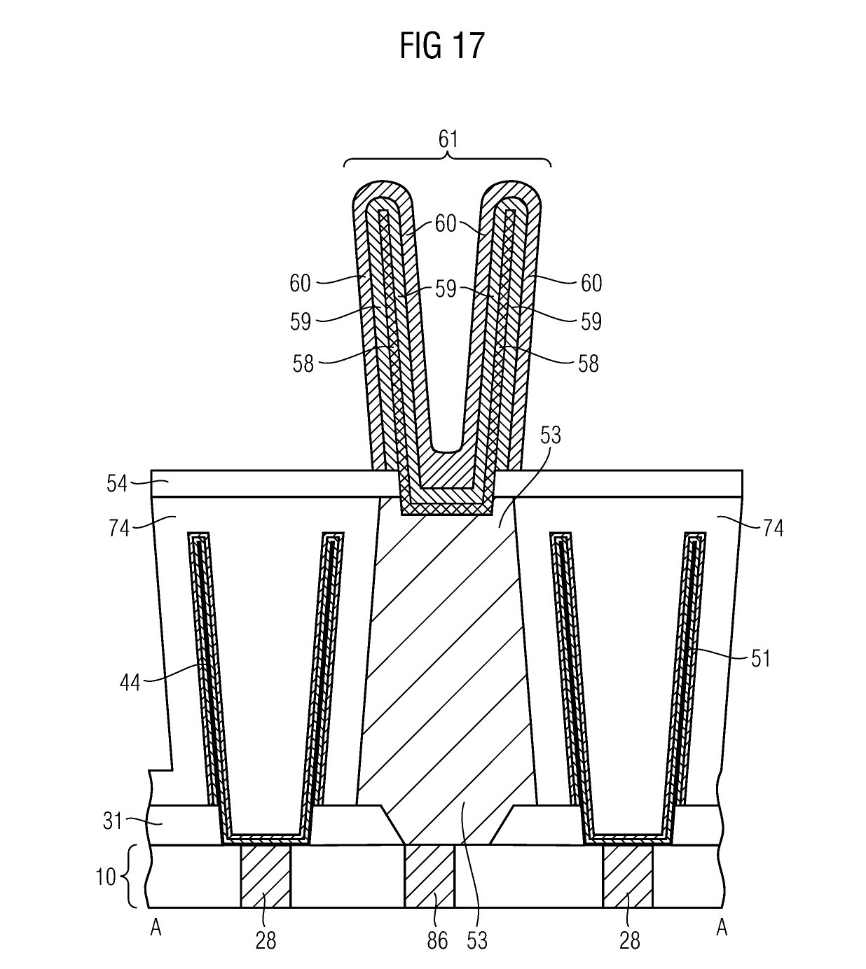

In further process, the second photoresist layer 56 and the second oxide layer 55 are removed. A dielectric layer 59 is deposited on an inner side and an outer side of the further first electrode 58. Additionally, a further second electrode 60 is deposited on an inner side and an outer side covering the further dielectric layer 59, as illustrated in FIG. 17. Thus, a further cylinder capacitor 61 is fabricated. As illustrated in FIG. 17, the further first electrode 58 is in contact via the conductive material 53 with the second contact pad 86. The further first and second electrode 58, 60 may include metallic material for example TiN, TaN, Ru, Ir and C. The further dielectric layer 59 may include HfOx, HfSiOx, HfAlOx, ZrOx, ZrSiOx, ZrAlOx, ZrAOx, whereby A is an element of the rare earth groups.

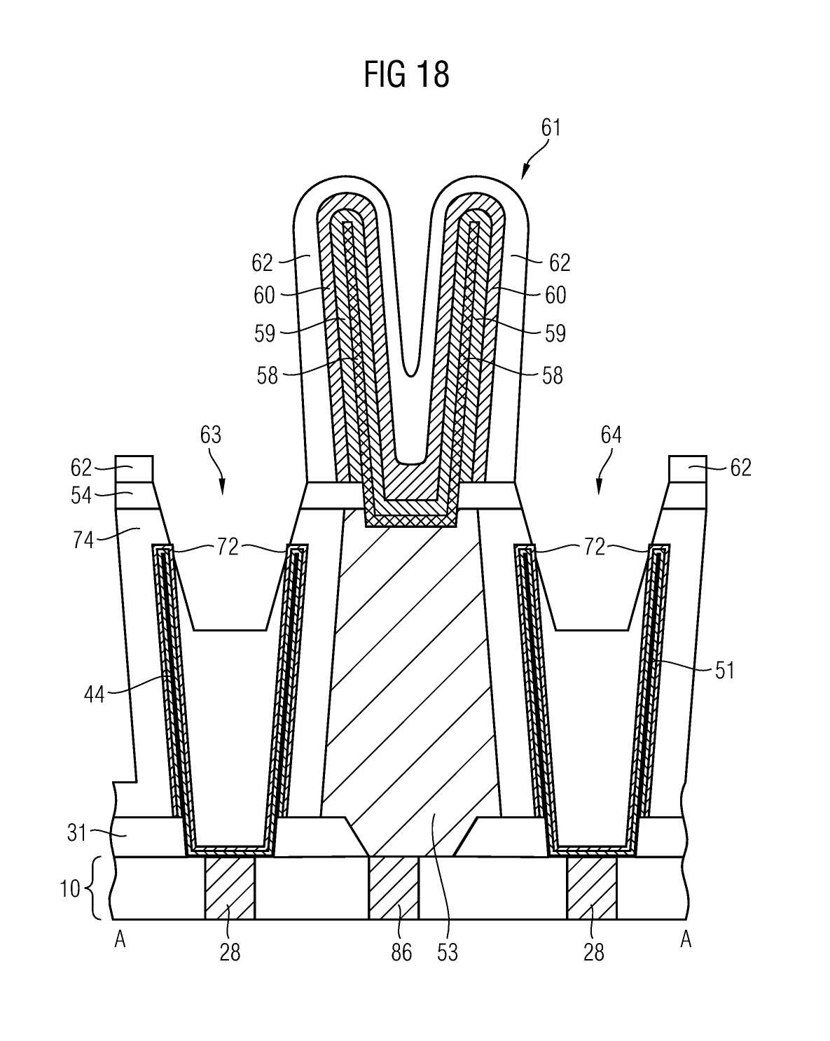

In further process, a hard mask 62 is deposited on the dielectric liner 54 and the further cylinder capacitor 61. The hard mask 62 is structured in an area above the inner region 48 of the adjacent cylinder capacitor 44 and the third cylinder capacitor 51 of the first level. Then the dielectric material 74 is removed from the inner part 48 of the cylinder capacitor 44 and the third cylinder capacitor 51 laying open a face of the second electrode 72 of the cylinder capacitor 44 and the third cylinder capacitor 51 as illustrated in FIG. 18. FIG. 18 illustrates the cylinder capacitor 44 and the third cylinder capacitor 51 with a contact hole 63, 64 that is arranged in an upper section of the inner region 48 of the cylinder capacitor 44 and the third cylinder capacitor 51 and that provide an access to a free face of the second electrodes.

In a further process, the hard mask 62 is removed from the surface of the dielectric liner 54 and from the further cylinder capacitor 61. In a further process, the contact hole 63 of the cylinder capacitor 44 and the further contact hole 64 of the third cylinder capacitor 51 are filled with a second electrical material 65.

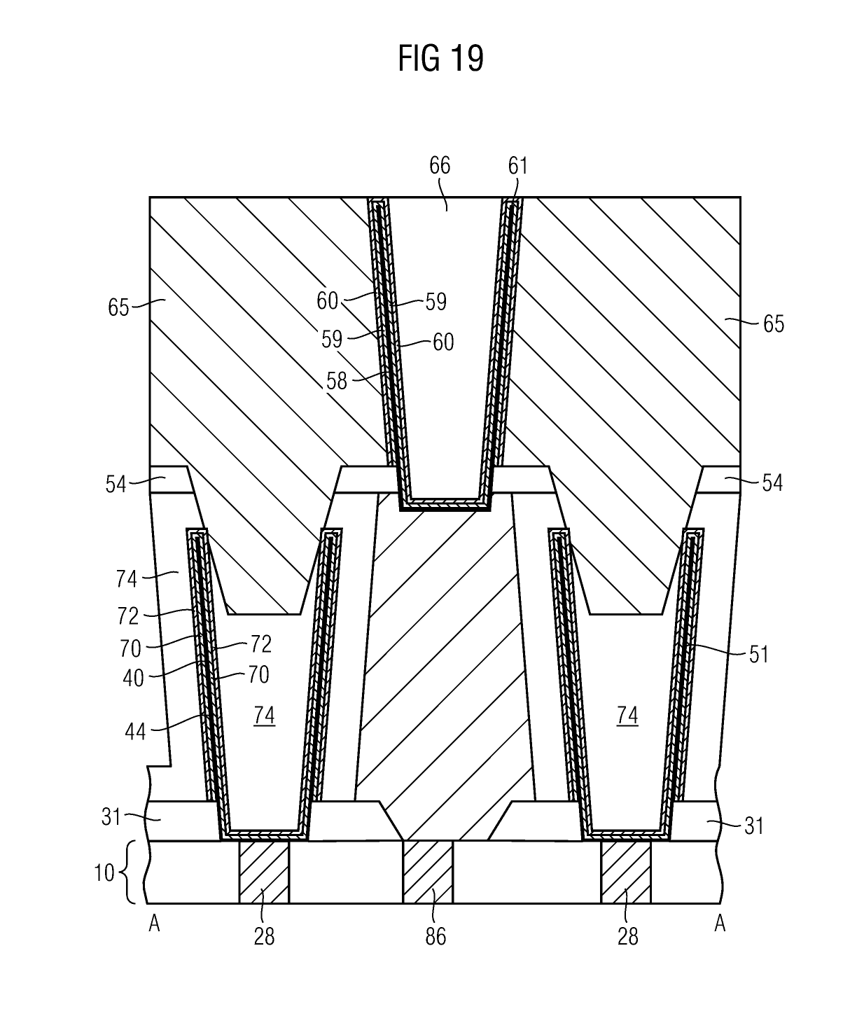

In addition, an inner part of the further cylinder capacitor 61 is filled with a further dielectric material 66 that is electrically insulating. This process is illustrated in FIG. 19. FIG. 19 illustrates the structure of the cylinder capacitor 44 with a first electrode 40 which is covered by a dielectric layer 70 on two sides that is at an outer and an inner side covered by a second electrode 72. At an inner side, the second electrode 72 is covered by the second conductive material 65, providing an electrical contact between the second electrodes 72 with the second conductive material 65. At an outer side, the second electrode 72 is covered by the dielectric material 74.

Furthermore, an upper part of the further cylinder capacitor 61 is illustrated in greater detail showing that the further first electrode 58 is covered at an inner and at an outer side by the further dielectric layer 59. The further dielectric layer is at the inner and the outer side covered by the further second electrode 60. At an outer side, the further second electrode 60 is covered by the second conductive material 65. At the inner side, the further second electrode 60 is covered by the further spacer material 66. Thus, the second electrode 72 of the cylinder capacitor 44, 50, 51 of the second level and the further second electrode 60 of the further cylinder capacitor 61 of the first level are connected to each other via the second conductive material 65. The second conductive material may include Ti or W or Ti and W. In another embodiment a stacked layer of Ti, TiW and W may be disposed.

Furthermore, a greater detail section is illustrated in the area of the further cylinder capacitor 61 adjacent to the conductive material 53. This detailed picture illustrates that only the further first electrode 58 is in contact with the conductive material 53. The further spacer material 66 is made of an electrically insulating material.

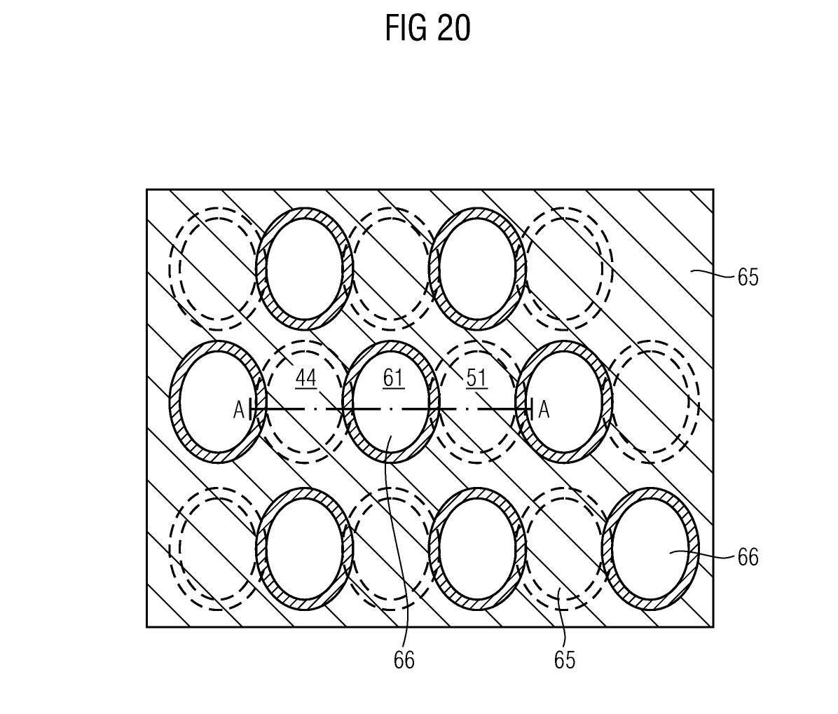

FIG. 20 illustrates a schematic view onto an arrangement of cylinder capacitors, wherein the cylinder capacitors are arranged in a first and in a second level, wherein the cylinder capacitors of the first and the second level are disposed in such a way that between two cylinder capacitors 44, 51 of a first level a further cylinder capacitor 61 of the second level is arranged. The further cylinder capacitor 61 of the second level is disposed above the first level and between two cylinder capacitors 44, 51 of the first level. In FIG. 20, the cylinder capacitors of the first level are illustrated by a circle with dotted lines. The further cylinder capacitors of the second level are illustrated as circles with a full line. The black bar in FIG. 20 illustrates the position of the sectional view of FIG. 19.

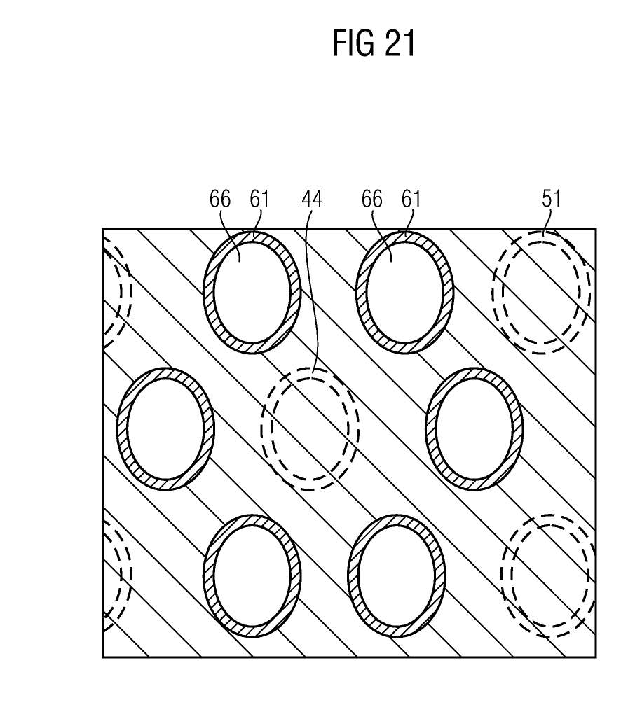

FIG. 21 illustrates another embodiment of a semiconductor memory with cylinder capacitors which are arranged in a first level and in a second level, wherein the cylinder capacitors 44, 51 of the first level are illustrated as circles with a full line and the further cylinder capacitors 61 of the second level are illustrated as circles with dotted lines. In this embodiment, six further cylinder capacitors 61 of the second level are arranged around one cylinder capacitor 44 of the first level. This layout is called a checkerboard layout.

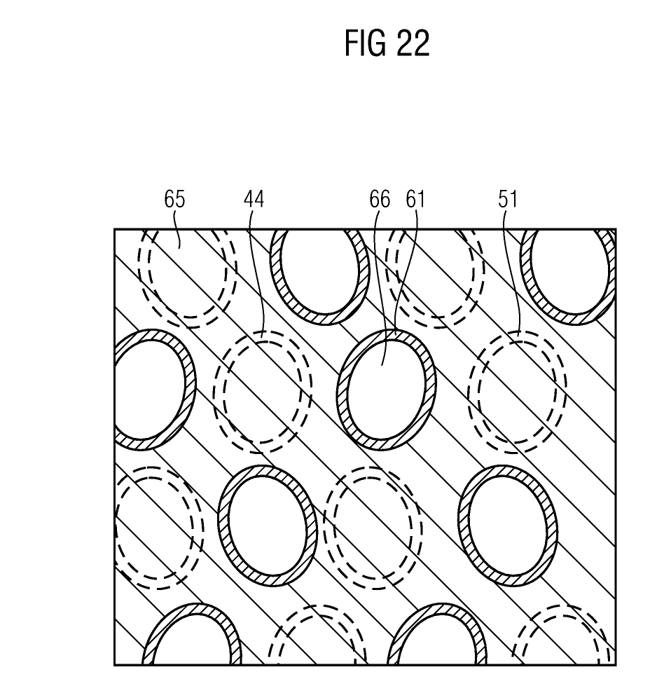

FIG. 22 illustrates another embodiment with cylinder capacitors 44, 51 in a first level and cylinder capacitors 61 in a second level. The cylinder capacitors 44, 51 in the first level are illustrated as a circle with a dotted line and the further cylinder capacitors 61 of the second level are illustrated as a circle with a full line. The illustrated arrangement is a wave-shaped layout wherein one cylinder capacitor of the first level is surrounded by four further cylinder capacitors of the second level.

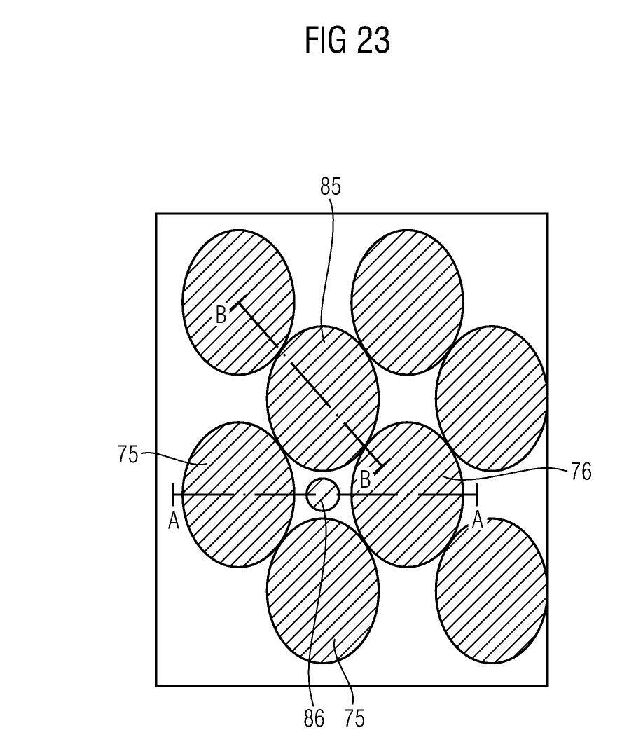

The FIGS. 23 to 32 illustrate another process for fabricating a semiconductor memory with block capacitors in a first and in a second level wherein the block capacitor having the shape of a pedestal.

FIG. 23 illustrates a top view on several block capacitors 75, 76, 85 that have the same structure and are arranged on a wafer substrate assembly 10. The block capacitors 75, 76, 85 are disposed in rings of four block capacitors that are adjacent to each other wherein within the ring a free space is arranged at which a free further contact pad 86 is located. In FIG. 23 a first sectional line A-A and a second sectional line B-B are illustrated.

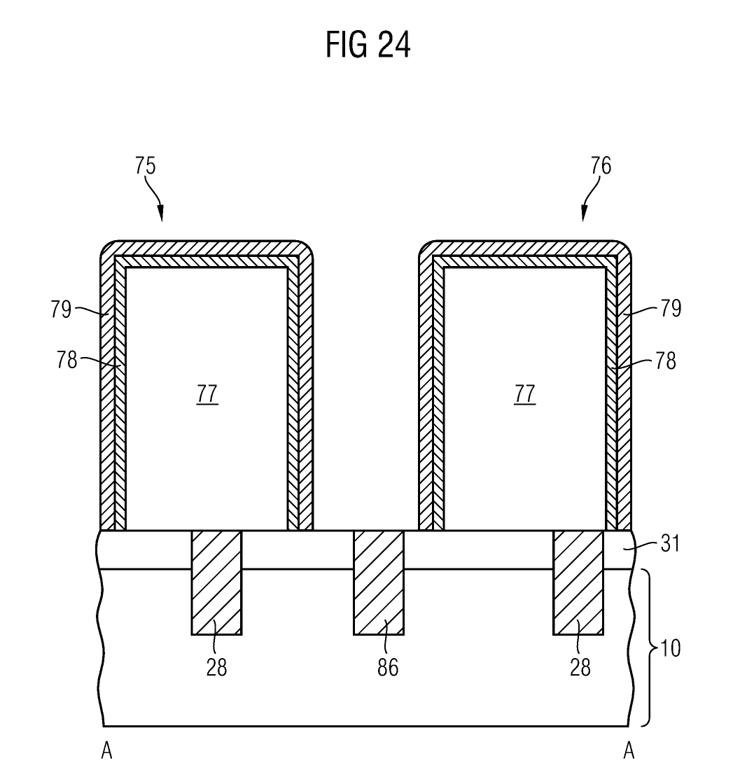

FIG. 24 illustrates a sectional view along the sectional line A-A of FIG. 23 with a wafer substrate assembly 10 including the same elements as the wafer substrate assembly 10 of FIG. 1, however, only the contact pads 28 the further contact pads 86 and the stop layer 31 are illustrated. On the stop layer 31, a first and a second block capacitor 75, 76 are arranged wherein a block capacitor 75, 76 include a pedestal electrode 77 which is covered by a third dielectric layer 78. The third dielectric layer 78 is covered by an additional second electrode layer 79. The pedestal electrode 77 and the additional second electrode layer 79 may include TiN, TaN, Ir or Ru. The third dielectric layer 78 may include HfOx, HfSiOx HfAlOx, ZrOx, ZrSiOx, ZrAlOx, ZrAOx whereby A is an element of the groups of rare earth elements. The pedestal electrode 77 of the first and the second block capacitor 75, 76 are connected with a respective contact pad 28. The first and the second block capacitor 75, 76 are fabricated with a fabrication process according to the FIGS. 1 to 7, wherein instead of a sleeve shape for the first electrode the pedestal electrode 77 with the shape of a pedestal was deposited on the etch stop layer 31.

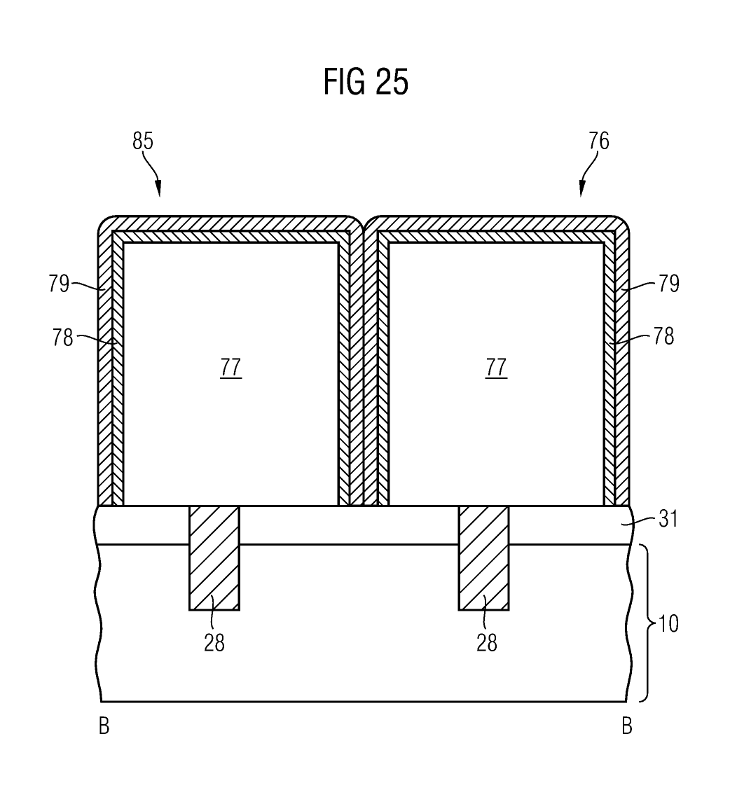

FIG. 25 illustrates a sectional view along the second sectional line B-B of FIG. 23 across two block capacitors 85, 76 that are in contact with the second electrode layer 79.

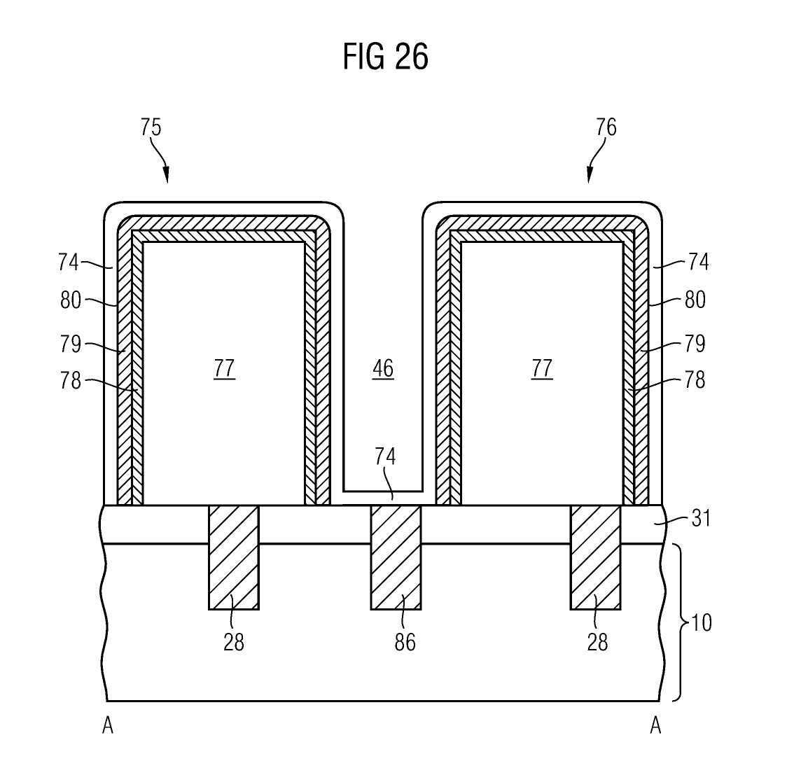

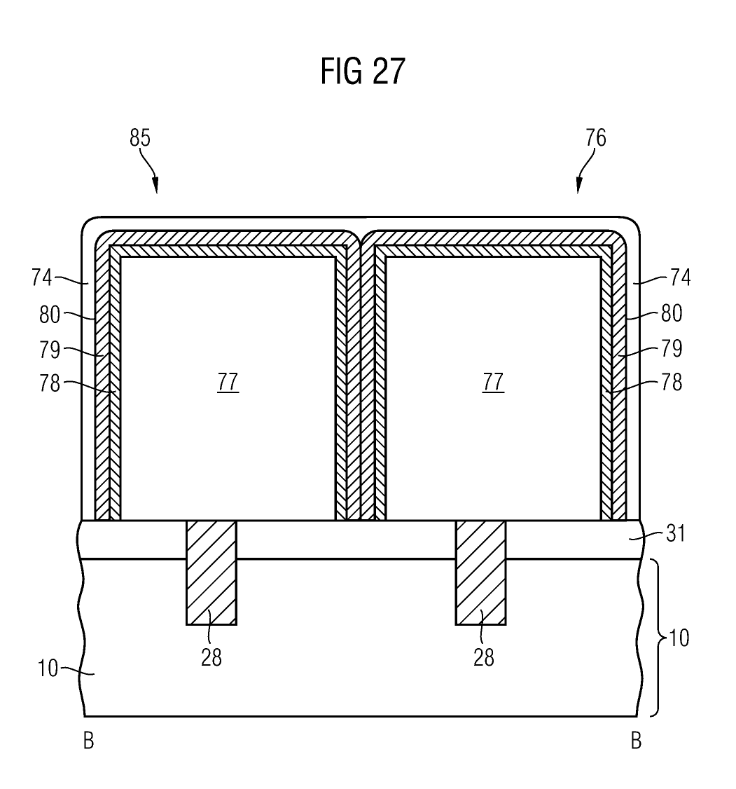

In further process, a second dielectric liner 80 is deposited on the second electrode layer 79 of the block capacitors 75, 76. Furthermore, a dielectric material 74 is deposited on the second dielectric liner 80 covering the further contact pad 86 and the etch stop layer 31 in a contact area 46 between two neighbouring block capacitors 75, 76. FIG. 26 illustrates this process step. FIG. 27 illustrates this process along the sectional line B-B.

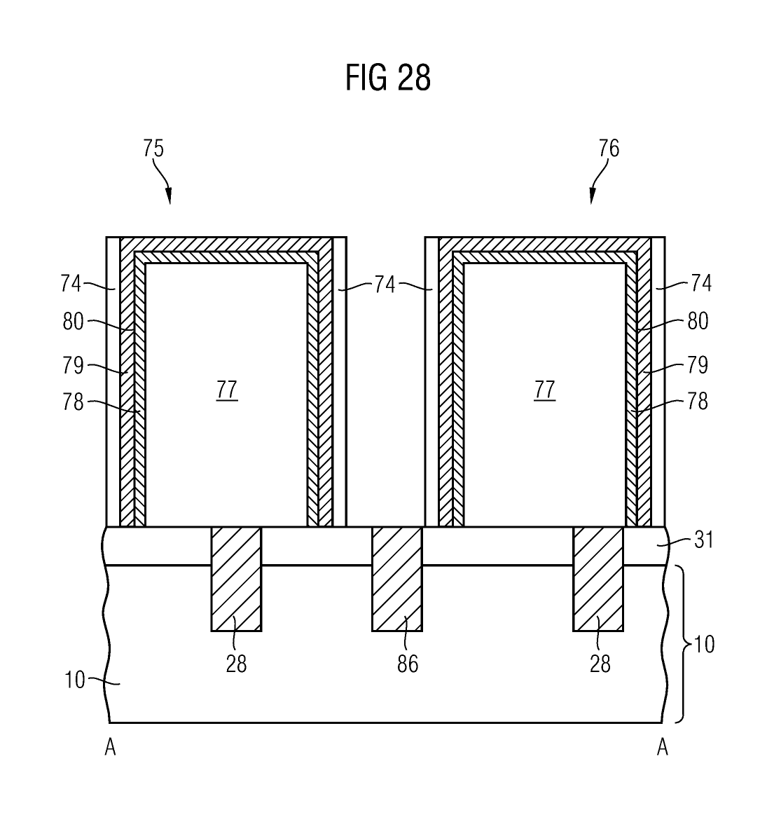

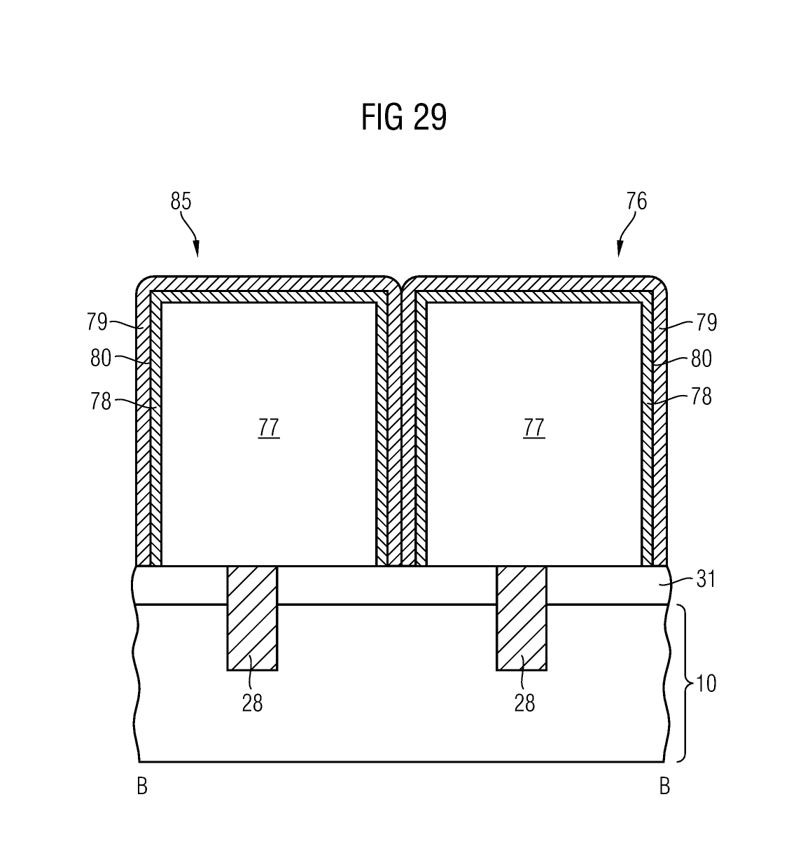

In further process, the dielectric material 74 is removed in the contact area 46 above the contact pad 68. The further contact pad 68 is laid open at the surface of the etch stop layer 31. This process is illustrated in FIG. 28. FIG. 29 illustrates the same process along the sectional plane B-B.

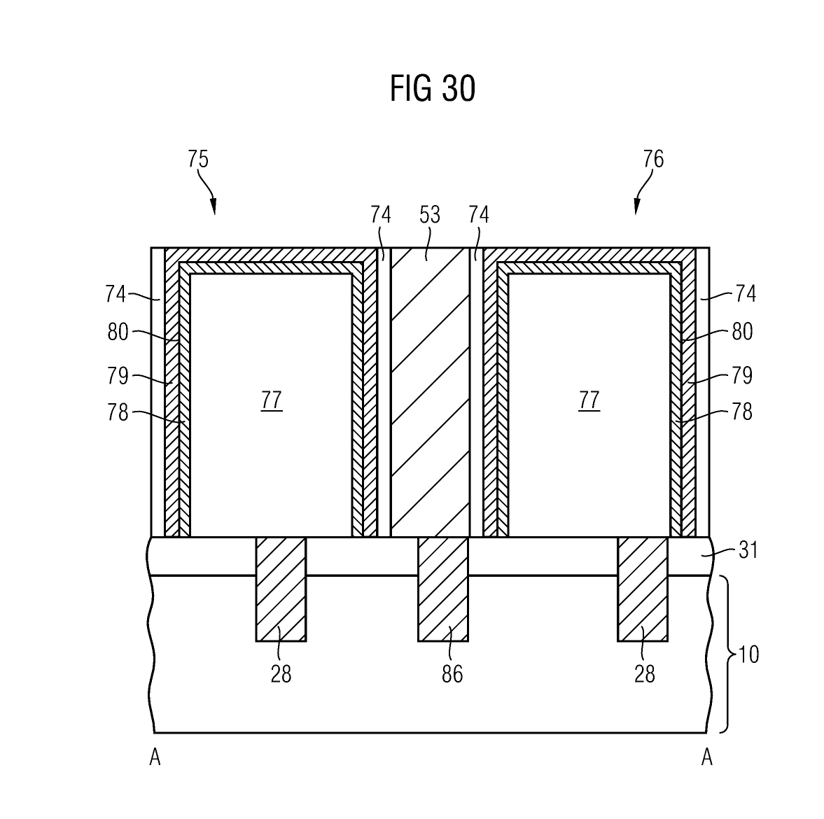

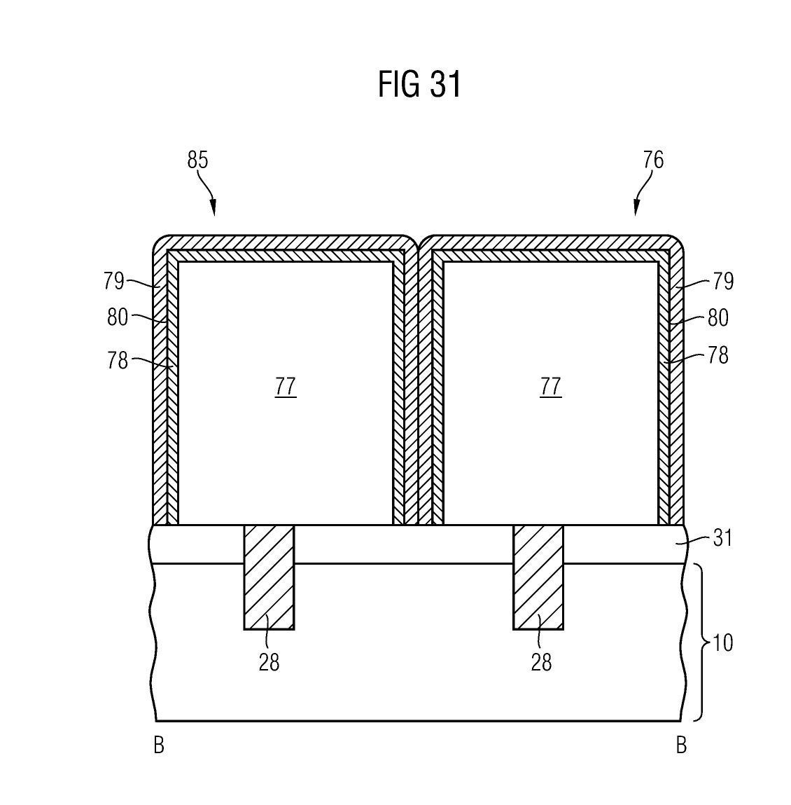

In one embodiment, the contact area 46 is filled with conductive material 53, e.g., polysilicon or metal. As a metal e.g., tungsten may be used. In one embodiment Ti or a combination of Ti and W is used. Furthermore, a stacked layer of a first layer made of Ti, a second layer made of TiW and a third layer made of W may be used, whereby the second layer is arranged between the first and third layer. The conductive material 53 is filled up to a plane equal to a surface of the first and second block capacitors 75, 76, as illustrated in FIG. 30. The conductive material 53 is electrically connected to the further contact pad 86. The conductive material 53 may include Ti or W or a combination of Ti and W. Furthermore, the conductive material may include a stacked layer of Ti, TiW and W. FIG. 31 illustrates the same situation as FIG. 30 in the sectional plane B-B.

In a following process step, a second dielectric liner 54 is deposited on the structure of FIG. 30 covering the second electrode layer 79, the dielectric material 74 and the conductive material 53. Then, a third, a fourth and a fifth block capacitor 81, 82, 83 are fabricated wherein the third, fourth and fifth block capacitors 81, 82, 83 are positioned above the conductive material 53 of the first level. The third, fourth and fifth block capacitors 81, 82, 83 are fabricated in a second level above the first level. The third, fourth and fifth block capacitor 81, 82, 83 include a pedestal electrode 77, which is covered by a third dielectric layer 78. The third dielectric layer 78 is covered by a second electrode layer 79. The second dielectric liner 54 is opened in a contact recess to the conductive material 53 before depositing the pedestal electrode 77. Thus, the pedestal electrodes 77 of the second level are electrically connected to the conductive materials 53 which are connected to the further contact pads 86 of the wafer substrate assembly. The third, fourth and fifth block capacitors 81, 82, 83 may have basically the same shape as the block capacitors 75, 78, 85 of the first level. The conductive materials 53 dispose contact elements for connecting the pedestal electrodes 77 of the second layer with the further contact pads 86.

Furthermore, free space between the third, fourth and fifth block capacitor 81, 82, 83 are filled with second conductive material 65 after the second dielectric layer 54 is opened above the block capacitors of the first level, thereby electrically connecting the second electrode layers 79 of the block capacitors 75, 76, 85 of the first level and the second conductive material 65 of the second level with the second electrode layers 79 of the block capacitors of the second level.

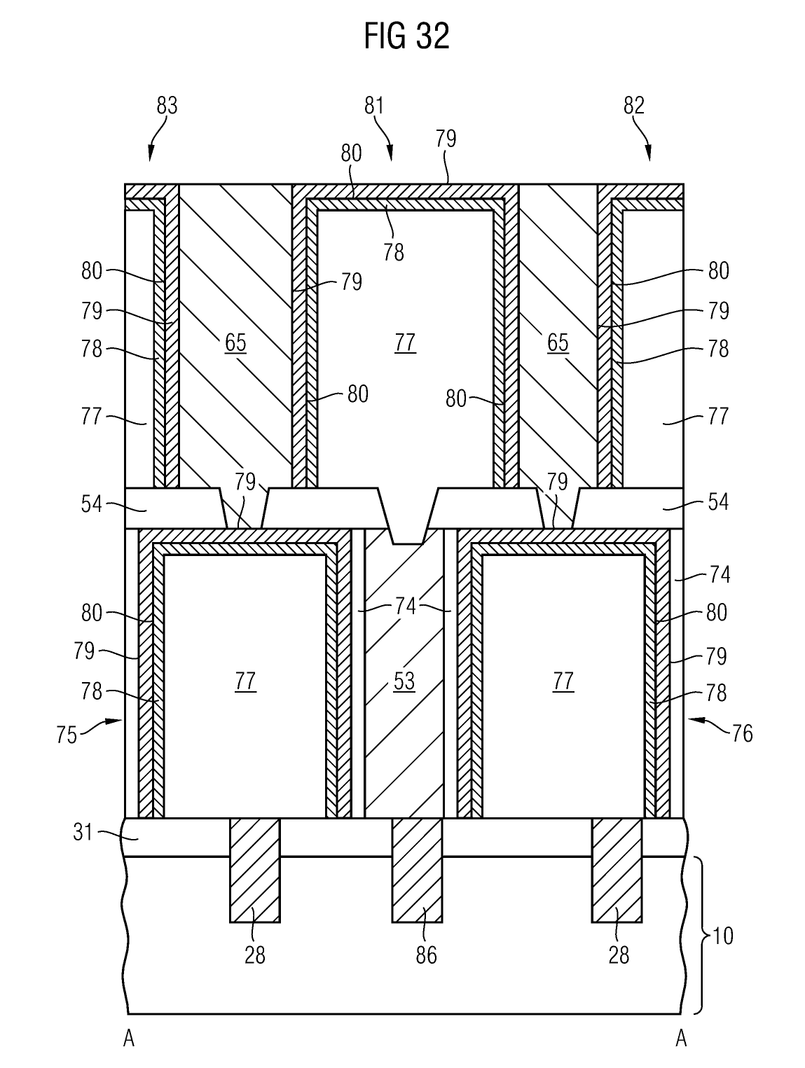

In the illustrated embodiment of FIG. 32, a first contact pad 28 is electrically connected to a block electrode 77 of a first block capacitor 75 of the first level. A further contact pad 86 is electrically connected via the conductive material 53 to a pedestal electrode 77 of a third block capacitor 81 of the second level. In the same way the other block capacitors 82, 83 of the second level are electrically connected by conductive material fillings 53 with further contact pads 86 of the wafer substrate assembly 10.

Furthermore, the second electrode layers 79 of the block capacitors 75, 76 of the first level are electrically connected to the second conductive material 65. The second conductive material 65 may include Ti or W or a mixture of Ti and W. Furthermore, the conductive material 65 may be a stacked layer of Ti, TiW and W. Furthermore, the second electrode layer 79 of the third, fourth and fifth block capacitors 81, 82, 83 of the second level are electrically connected to the second conductive material 65. Thus, the second electrode layers of the block capacitors of the first and the second level are electrically connected.

Therefore, the block capacitors of the first and the second level are accessible via the contact pads 28 and the further contact pads 86 and the transistors of the wafer substrate assembly 10. Thus, it is possible to provide a larger number of block capacitors on a predetermined area of the wafer substrate since two levels are used for the arrangement of the block capacitors. This is the same with the arrangement of FIG. 19 and 22 with the cylinder capacitors.

The block capacitors may be disposed in a regular layout as it is illustrated in FIG. 20 for the cylinder capacitors. Furthermore, the block capacitors of the first and the second level may be arranged in the checkerboard layout as it is illustrated in FIG. 21 for the cylinder capacitors. In one embodiment, the block capacitors may also be disposed in a wave-shaped layout as it is illustrated in FIG. 22 for the cylinder capacitors.

In another embodiment, there may be a third layer on the second layer that includes the same structure as the second layer and that includes capacitor elements that are connected with a first electrode with the further contact pad 86 of the substrate.

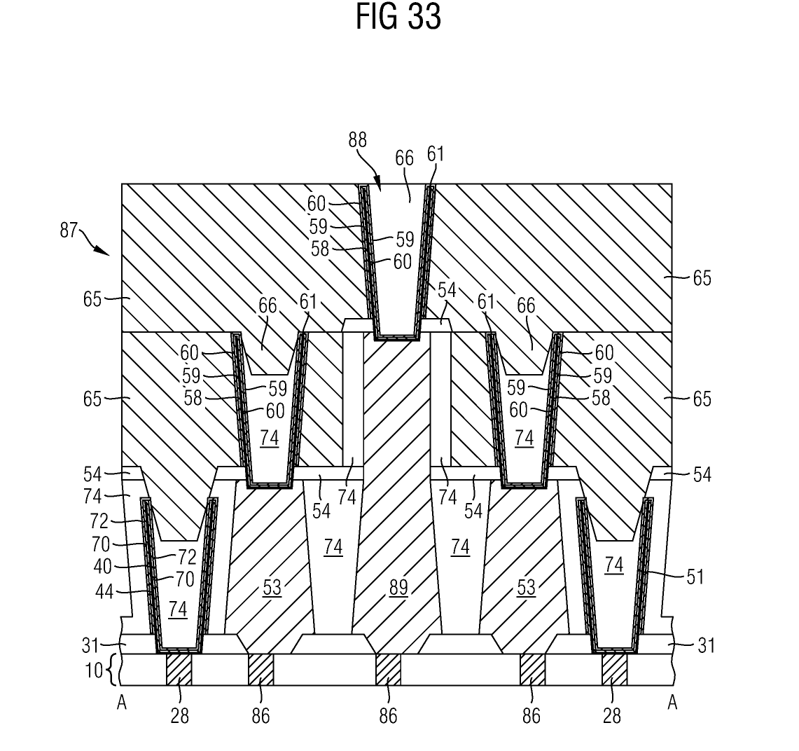

FIG. 33 illustrates a first embodiment with a third layer 87 including a further cylinder capacitor 88 that is electrically connected with a second contact pad 86 via a further connection element 89 made of conductive material that extends from the third layer 89 via the first and second layer to the second contact pad 86 of the layer 10. The connection element 89 is electrically insulated to the surrounding material by dielectric material 74.

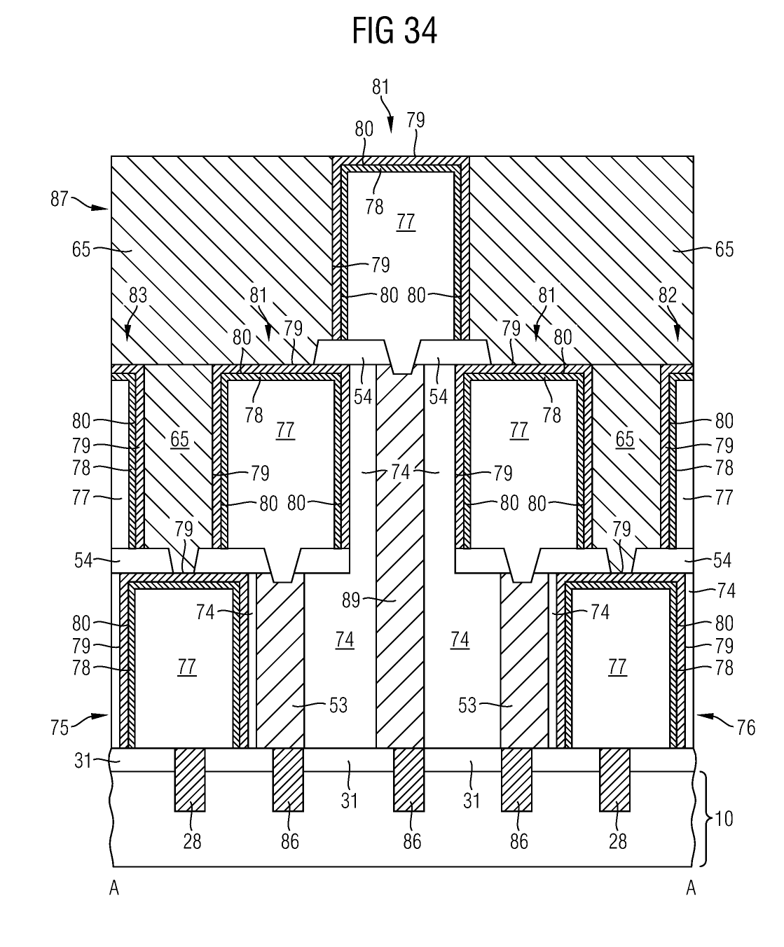

FIG. 34 illustrates one embodiment with a third layer 87 including a further block capacitor 90. The further block capacitor 90 is electrically connected via a connection element 89 made of conductive material with a second contact pad 86 of the first layer 10. The connection element 89 extends from the third layer 87 via the second and first layer to the layer 10.

Although specific embodiments have been illustrated and described herein, it will be appreciated by those of ordinary skill in the art that a variety of alternate and/or equivalent implementations may be substituted for the specific embodiments illustrated and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit having a memory comprising:
a plurality of memory cells with capacitor elements and further capacitor elements;
a substrate layer with contact pads and further contact pads, the capacitor elements being disposed in a first level on the substrate layer and connected with the contact pads;
the further capacitor elements being disposed in a second level above the first level; contact elements being disposed between the capacitor elements and connected with the further contact pads; and
the further capacitor elements being disposed above the contact elements and being connected with the contact elements.

2. The integrated circuit of claim 1, comprising wherein the capacitor elements and the further capacitor elements are cylinder capacitors.

3. The integrated circuit of claim 1, comprising wherein the capacitor elements and the further capacitor elements are block capacitors.

4. The integrated circuit of claim 1, wherein the capacitor elements and the further capacitor elements comprise a first electrode, a dielectric layer and a second electrode; and the dielectric layer is disposed between the first electrode and the second electrode.

5. The integrated circuit of claim 1, comprising wherein the second electrodes of the capacitor elements and the second electrodes of the further capacitor elements being connected together via electrical conductive material that is disposed in the first and the second level.

6. The integrated circuit of claim 1, comprising wherein an electrically insulating layer is arranged between the first and the second level.

7. The integrated circuit of claim 2, comprising wherein an inner space of the cylinder capacitor of the first level is filled with dielectric material.

8. The integrated circuit of claim 2, comprising wherein an inner space of the cylinder capacitor of the first level is filled with a dielectric material; and a recess is disposed in an upper part of the dielectric material adjoining the second electrode of the cylinder capacitor; an electric conductive material is filled in the recess, wherein the conductive material being connected with the second electrodes of the cylinder capacitors of the first level.

9. The integrated circuit of claim 8, comprising wherein the second electrodes of the cylinder capacitors of the first level are connected with the conductive material.

10. The integrated circuit of claim 8, comprising wherein a second electrode of a cylinder capacitor of the second level is connected with a conductive material of the second level; and the conductive material of the second level being electrically connected with the conductive material of the first level.

11. The integrated circuit of claim 1, comprising wherein the capacitor elements of the first level and the further capacitor elements of the second level comprising a first electrode, a dielectric layer and a second electrode; and the first electrodes of capacitor elements being connected with the contact pads of the substrate layer, wherein the second electrodes of the capacitor elements and the further capacitor elements being connected.

12. The integrated circuit of claim 2, comprising wherein a dielectric material is arranged between the cylinder capacitors of the first level; and a cylinder capacitor being connected by a bridge element with an adjacent cylinder capacitor of the first level; the bridge element mechanically connecting the capacitor elements of the first level.

13. The integrated circuit of claim 1, comprising wherein the capacitor elements of the second layer is embedded in electrical conductive material.

14. The integrated circuit of claim 1, comprising wherein a further capacitor element is at least partially arranged in a lateral direction above a capacitor element.

15. The integrated circuit of claim 2, comprising wherein a cylinder capacitor of the second level is partially arranged in an area above a space between two cylinder capacitors of the first level extending at least partially in the space of the first level.

16. An integrated circuit having a memory comprising:
memory cells with capacitor elements and memory cells with further capacitor elements;
a substrate layer with contact pads and further contact pads, the contact pads being connected with the capacitor elements;
the capacitor elements are disposed in a first level on the substrate layer;
the further capacitor elements are disposed in a second level above the first level;
between the capacitor elements contact elements are disposed, the further capacitor elements are disposed above the contact elements, the contact elements are connected with the further capacitor elements and with the further contact pads arranged under the contact elements; and
the capacitor elements and the further capacitor elements comprising a first electrode, a dielectric layer and a second electrode, wherein the dielectric layer is disposed on the first electrode and the second electrode that is disposed on the dielectric layer, wherein the second electrodes of the capacitor elements and the further capacitor elements are connected via electrical conductive material that is disposed at least partially in the first and the second level.

17. The integrated circuit of claim 16, comprising wherein the capacitor element is a cylinder capacitor.

18. The integrated circuit of claim 17, comprising wherein the capacitor element is a block capacitor.

19. An integrated circuit having a Memory comprising memory cells with capacitor elements and memory cells with further capacitor elements;
a substrate layer with contact pads and further contact pads;
the contact pads being connected with the capacitor elements;
the capacitor elements are disposed in a first level on the substrate layer;
the further capacitor elements are disposed in a second level above the first level;
between the capacitor elements contact elements are disposed;
the further capacitor elements are disposed above the contact elements;
the contact elements are connected with the further capacitor elements and with the further contact pads arranged in the substrate layer under the contact elements;
the further capacitor elements and the capacitor elements are cylinder capacitors;
an inner part of the further cylinder capacitors are filled with dielectric material;
recesses are disposed in an upper part of the dielectric material adjoining the second electrodes of the cylinder capacitors;
an electric conductive material is arranged in the recesses; and
the conductive material is connected with the second electrodes of the cylinder capacitors of the capacitor elements.

20. The integrated circuit of claim 19, wherein the first electrode comprises at least one material of the group TiN, TaN, Ru, Ir and Cu.

21. The integrated circuit of claim 19, wherein the second electrode comprises at least one material of the group comprising TiN, TaN, Ru, Ir and Cu.

22. The integrated circuit of claim 19, wherein the first electrode is a stacked layer with a first layer comprising Ti, a second layer comprising TiW and a third layer comprising W.

23. The memory of claim 4, wherein the second electrode is a stacked layer with a first layer comprising Ti, a second layer comprising TiW and a third layer comprising W.

24. A method of fabricating an arrangement with capacitor elements comprising the steps of:
providing a substrate layer with first and second contact pads;
depositing a first layer with capacitor elements with at least a first electrode;
depositing the first electrodes at least partially on the first contact pads;
providing contact elements on the second contact pads;
depositing a second layer with further capacitor elements on the first layer; and
the further capacitor elements being fabricated with first electrodes that are at least partially deposited on the contact elements.

25. The method of claim 24 comprising:
depositing a first isolating layer on the substrate layer;
forming first recesses in the first isolating layer extending to the first contact pads;
forming the capacitor elements at least partially in the first recesses;
forming second recesses beside the capacitor elements above second contact pads in the first isolating layer extending to the second contact pads; and
depositing contact elements in the second recesses in contact with the second contact pads.

26. The method of claim 24 comprising:
depositing a second isolating layer on the first isolating layer;
forming third recesses above the contact elements in the second isolating layer extending to the contact elements; and
forming further capacitor elements in the third recesses with first electrodes being deposited at least partially in contact with the contact elements.

27. The method of claim 24 comprising:
depositing a first isolating layer on the substrate layer;
forming first recesses in the first isolating layer extending to first contact pads;
forming the capacitor elements in the first recesses with first electrodes, with a dielectric layers and with a second electrodes;
forming second recesses over second contact pads in the first isolating layer extending to the second contact pads;
forming contact elements in the second recesses in contact with the second contact pads; depositing a second isolating layer on the first isolating layer;
forming third recesses above the contact elements in the second isolating layer extending to the contact elements;
forming further capacitor elements with first electrodes, dielectric layers and second electrodes in the third recesses;
depositing the first electrodes being at least partially in contact with the contact elements; forming fourth recesses in the first and second isolating layer extending to second electrodes of the capacitor elements and to second electrodes of the further capacitor elements; and
depositing a conductive material in the fourth recesses electrically connecting the second electrodes of the capacitor elements and the second electrodes of the further capacitor elements.

28. The method of claim 24 comprising:
depositing a third isolating layer on the first isolating layer covering the capacitor elements and the contact elements;
depositing the second isolating layer on the third isolating layer;
forming third recesses above the contact elements in the second and the third isolating layer extending to the contact elements;
forming further capacitor elements in the third recesses with first electrodes; and
depositing the first electrodes at least partially in contact with the contact elements.

29. The method of claim 24, comprising: forming the capacitor elements and the further capacitor elements in the shape of cylinder capacitors.

30. The method of claim 24, comprising:
forming the capacitor elements and the further capacitor elements in the shape of block capacitors.

31. The method of claim 24, comprising:
forming the capacitor elements in shapes of cylinder capacitors;
filling an inner part of the cylinder capacitors with dielectric material before forming the further capacitor elements;
forming fifth recesses in the dielectric material extending to the second electrodes of the capacitor elements; and
depositing electric conductive material in the fifth recesses in contact with the second electrodes of the capacitor elements.

32. The method of claim 24, comprising:
forming the capacitor elements in shapes of cylinder capacitors;
filling inner parts of the cylinder capacitors with dielectric material before forming the further capacitor elements;
forming fifth recesses in the dielectric material of the u-forms extending to the second electrodes of the capacitor elements; and
depositing electric conductive material in the fifth recesses and on the first layer in contact with the second electrodes of the capacitor elements and the second electrodes of the further capacitor elements.

33. An arrangement of capacitor elements comprising:
capacitor elements and further capacitor elements;
a substrate layer with contact pads and further contact pads; the capacitor elements being disposed in a first level on the substrate layer and connected with the contact pads;
the further capacitor elements being disposed in a second level above the first level;
contact elements being disposed between the capacitor elements and connected with the further contact pads; and
the further capacitor elements being disposed above the contact elements and being connected with the contact elements.

34. The arrangement of claim 33, comprising wherein the capacitor elements and the further capacitor elements are cylinder capacitors.

35. The arrangement of claim 33, comprising wherein the capacitor elements and the further capacitor elements are block capacitors.

36. The arrangement of claim 33, wherein the capacitor elements and the further capacitor elements comprise a first electrode, a dielectric layer and a second electrode; the dielectric layer being disposed on the first electrode and the second electrode being disposed on the dielectric layer; the second electrodes of the capacitor elements and the second electrodes of the further capacitor elements being connected together via electrical conductive material that is disposed in the first and the second level.

37. The arrangement of claim 33, comprising wherein an electrically insulating layer that is arranged between the first and the second level.

38. The arrangement of claim 34, comprising wherein an inner area of the cylinder capacitor of the first level is filled with dielectric material.

39. The arrangement of claim 34, comprising wherein an inner area of the cylinder capacitor of the first level is filled with a dielectric material; a recess being disposed in an upper part of the dielectric material adjoining the second electrode of the cylinder capacitor; an electric conductive material being filled in the recess, wherein the conductive material being connected with the second electrodes of the cylinder capacitors of the first level.

40. The arrangement of claim 34, comprising wherein the second electrodes of the cylinder capacitors of the first level being connected with the conductive material.

41. The arrangement of claim 40, comprising:
a second electrode of a cylinder capacitor of the second level being connected with a conductive material of the second level; and
the conductive material of the second level being electrically connected with the conductive material of the first level.

42. The arrangement of claim 33, wherein the capacitor elements of the first level and the further capacitor elements of the second level comprise a first electrode, a dielectric layer and a second electrode; the first electrodes of capacitor elements being connected with the contact pads of the substrate layer, wherein the second electrodes of the capacitor elements and the further capacitor elements being connected.

43. The arrangement of claim 34, comprising wherein a dielectric material being arranged surrounding the cylinder capacitor of the first level; a cylinder capacitor being connected by a bridge element with an adjacent cylinder capacitor of the first level; the bridge element extending from the substrate layer up to an upper end of the cylinder capacitor mechanically connecting the capacitor elements of the first level.

44. An integrated circuit having a memory comprising:
means for providing a plurality of memory cells with capacitor elements and further capacitor elements;
means for providing a substrate layer with contact pads and further contact pads, the capacitor elements being disposed in a first level on the substrate layer means and connected with the contact pads;
the further capacitor elements being disposed in a second level above the first level; contact elements being disposed between the capacitor elements and connected with the further contact pads; and
the further capacitor elements being disposed above the contact elements and being connected with the contact elements.
